(19) United States
(12) Patent Application Publication
(10) Pub. No.: US 2011/0249134 A1
(43) Pub. Date: Oct. 13, 2011

(54) SEMICONDUCTOR DEVICE WITH CONDUCTIVE TRENCHES TO CONTROL ELECTRIC FIELD

(75) Inventors: Aaron M. Dennison-Gibby, San Francisco, CA (US); David W. Ritter, San Jose, CA (US); Philip Golden, Menlo Park, CA (US); Carl Warren Craddock, San Francisco, CA (US); I-Shan Sun, San Jose, CA (US)

(73) Assignee: INTERSIL AMERICAS INC., Milpitas, CA (US)

(21) Appl. No.: 12/938,481

(22) Filed: Nov. 3, 2010

Related U.S. Application Data
(60) Provisional application No. 61/321,972, filed on Apr. 8, 2010.

(51) Int. Cl. H04N 5/228; H01L 31/18; G05F 1/10; H01L 31/0224

(52) U.S. Cl. 348/222.1; 257/459; 438/98; 327/540; 257/E31.124; 348/E05.031

(57) ABSTRACT

An imaging system, semiconductor device, and method of manufacture of a photo-detector device are disclosed. For example, an imaging system is disclosed, which includes a photo-detector unit including a plurality of conductive trenches formed within the photo-detector unit, and a plurality of electrical contacts, each electrical contact connected to a respective conductive trench. The imaging system further includes a light data processor unit coupled to an output of the photo-detector unit to convert an analog signal received from the photo-detector unit to a digital signal, a processing unit coupled to an output of the light data processor unit to generate a control signal in response to the digital signal, and a display unit coupled to an output of the processing unit to vary the intensity of an image displayed in response to the control signal.

### CROSS REFERENCE TO RELATED APPLICATIONS

This application is related to U.S. Provisional Patent Application Ser. No. 61/321,972 (attorney docket number SE-2785-TD) entitled “SEMICONDUCTOR DEVICE WITH CONDUCTIVE TRENCHES TO CONTROL ELECTRIC FIELD,” filed on Apr. 8, 2010 and incorporated herein by reference. This application hereby claims to the benefit of U.S. Provisional Patent Application Ser. No. 61/321,972.

### BRIEF DESCRIPTION OF THE DRAWINGS

Understanding that the drawings depict only exemplary embodiments and are not therefore to be considered limiting in scope, the exemplary embodiments will be described with additional specificity and detail through the use of the accompanying drawings, in which:

FIG. 1 is a block diagram showing an exemplary system that can be utilized to implement one embodiment of the present invention;

FIG. 2 is a side elevation, cross-sectional view of a semiconductor device that can be utilized to implement one embodiment of the present invention;

FIG. 3 is a flowchart showing an exemplary process that can be utilized to fabricate the semiconductor device shown in FIG. 2;

FIG. 4 is a side elevation, cross-sectional view of a semiconductor device that can be utilized to implement a second embodiment of the present invention; and

FIG. 5 is a flowchart showing an exemplary process that can be utilized to fabricate the semiconductor device shown in FIG. 4.

In accordance with common practice, the various described features are not drawn to scale but are drawn to emphasize specific features relevant to the exemplary embodiments.

### DETAILED DESCRIPTION

In the following detailed description, reference is made to the accompanying drawings that form a part hereof, and in which are shown by way of illustration specific illustrative embodiments. However, it is to be understood that other embodiments may be utilized and that logical, mechanical, and electrical changes may be made. Furthermore, the method presented in the drawing figures and the specification is not to be construed as limiting the order in which the individual acts may be performed. The following detailed description is, therefore, not to be construed in a limiting sense.

Embodiments of the present invention provide a semiconductor device with a plurality of conductive trenches, which are utilized to control an electrical field within the semiconductor device. In some embodiments, the semiconductor device is a silicon-based semiconductor device. In one embodiment, the semiconductor device is a photo-detector device, such as is utilized, for example, in a time-of-flight receiver for optical sensing. In some embodiments, the semiconductor device is a photodiode operating with maximum sensitivity in the infrared spectrum (e.g., 850 nm wavelength).

Specifically, multiple conductive trenches are formed in a semiconductor device. The area between the conductive trenches defines the active area of the semiconductor device. An electrical contact is attached to each conductive trench. For example, if the semiconductor device is a photo-detector device, the electrical contacts extend the control connections of a buried semiconductor structure (e.g., diode, transistor) to external terminals to facilitate access to the control connections in the device via the conductive trenches, in order to enable a designer to externally control the electric potentials of the trenches. For example, the control connections in a photo-detector device can be a plurality of cathode connections in a photodiode. A voltage signal can be applied to each electrical contact to control the electrical field within the active area of the semiconductor device. In one embodiment, a differential voltage signal is applied to the electrical contacts of a plurality of conductive trenches formed within a photo-detector device, in order to control and maximize the magnitude of the lateral electric field within the active areas of the photo-detector device. Consequently, a semiconductor device with conductive trenches provides increased control of the electrical field within the device. For example, utilizing conductive trenches with contacts in a photo-detector device provides significantly greater control of the lateral electric field within the device, which results in much higher operating frequencies for the device, and therefore, more accurate time-of-flight detections than those of existing photo-detector devices.

Additionally, a semiconductor device with conductive trenches and contacts is more compatible with state-of-the-art Complementary Metal-Oxide Semiconductor (CMOS) processes or technologies that utilize low supply or drive voltages. Furthermore, if the semiconductor device is a photo-detector device, the efficiency of the photo-detector device is improved over that of conventional photo-detector devices, because the extension of the depletion region in the device is defined by the depth of a trench rather than the depth of a diffused well (e.g., diffused wells are utilized in existing photo-detector devices). As such, a deep, thin trench in a semiconductor device, such as a photo-detector device, provides an optimal fill factor and efficiency factor for the device. In some embodiments, such as, for example, a photo-detector device utilized in a proximity sensor application or light sensor application, the kT/C noise (i.e., thermal noise, T, in the presence of a filtering capacitor, C) can be improved with a capacitor located externally to the photo-detector device involved.

Furthermore, a photo-detector device with conductive trenches and contacts provides higher frequency demodulation and, therefore, more accurate time-of-flight measurements than existing photo-detector devices. As such, the stronger lateral electric field produced in such a photo-detector device improves collection efficiency and, therefore, the signal-to-noise ratio of the device. Also, the achievable sensitivity of the photo-detector device is improved due to the increased volume of the depletion regions in the device caused by the trench formation process. As such, a photo-detector device is provided that can achieve excellent photosensitivity due to the designer's ability to control the definition of the depletion region with the trench formations involved.

In one embodiment, two conductive trenches are formed with different depths. Consequently, a user is enabled to apply a differential voltage or a fixed voltage to either conductive trench. In this embodiment, the device active region is completely surrounded by a trench and a diffused buried layer, which minimizes trench-to-substrate leakage current. Also, in one embodiment, punch-through regions with increased doping levels (compared to the intrinsic region) are formed at the boundaries between the intrinsic region and the conductive trenches. Consequently, the trench-to-trench leakage currents in the semiconductor device can be significantly reduced.

FIG. 1 is a block diagram showing a system 100, which can be utilized to implement one embodiment of the present invention. For example, system 100 can be utilized to implement a CMOS image sensor, a proximity sensor, or an ambient light sensor. Also, for example, system 100 can be utilized to implement a digital camera, a handheld/portable display, a Personal Digital Assistant (PDA), a smart phone, or any type of system that utilizes a semiconductor device such as, for example, a photo-detector device for proximity sensor or light sensor applications. For example, in a proximity sensor application, such a photo-detector device can be utilized in a cellular phone to determine the closeness of a user's face, by detecting the strength of an infrared (IR) signal reflected off the face. The phone's screen can be turned on or off in response to the reflected signal strength. For example, to conserve battery power, the screen is turned off as the phone is placed near the user's ear, and the screen is turned on as the phone is moved away. As another example, in a light sensor application, such a photo-detector device can be utilized in a laptop computer to sense the intensity of the ambient light, in order to adjust the brightness of the computer's screen to a comfortable level for the user.

System 100 includes a photo-detector unit 102, a light data processor unit 104, a processor unit 108, and a display unit 110. For example, photo-detector unit 102 can be designed to detect and demodulate incident light (i.e., light that directly strikes the surface of the photo-detector unit) within the visible frequency range, IR light, or light within frequencies above the visible range. Also, for example, light data processor unit 104 can be or include an analog signal processor (ASP) and an analog-to-digital converter (ADC), which converts a demodulated light signal received from photo-detector 102 to a digital signal. Processor unit 108 can be, for example, a digital signal processor (DSP), or a microprocessor. Display unit 110 can be, for example, an optical light emitting diode (OLED) display, or a liquid crystal display (LCD). The digital signal is coupled from light data processor unit 104 to processor unit 108. In response to the digital signal, processor unit 108 outputs a control signal to display unit 110 to control the intensity of the image to be displayed.

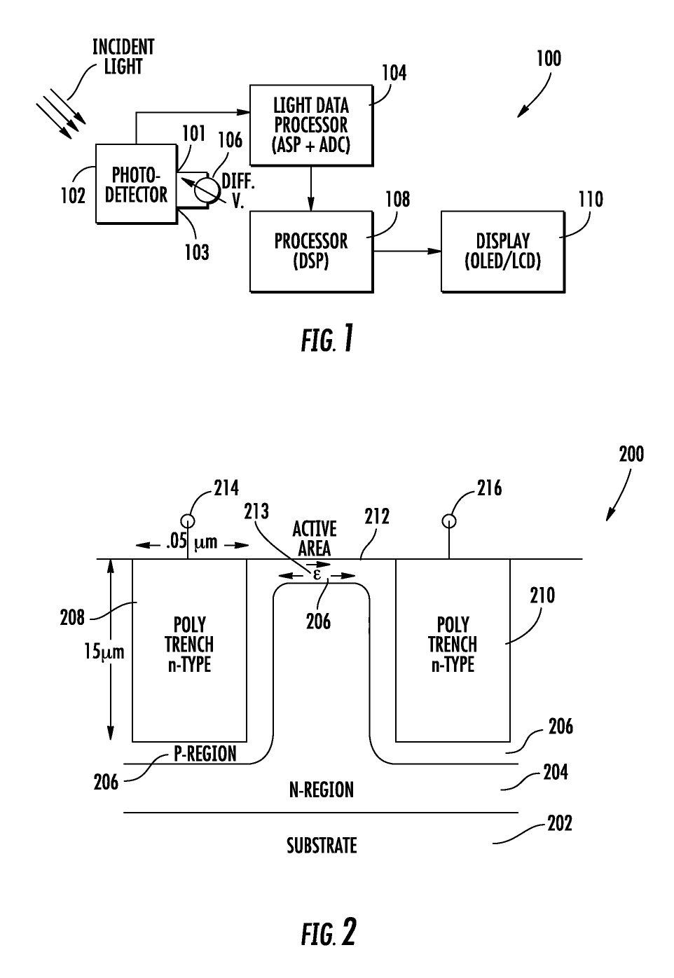

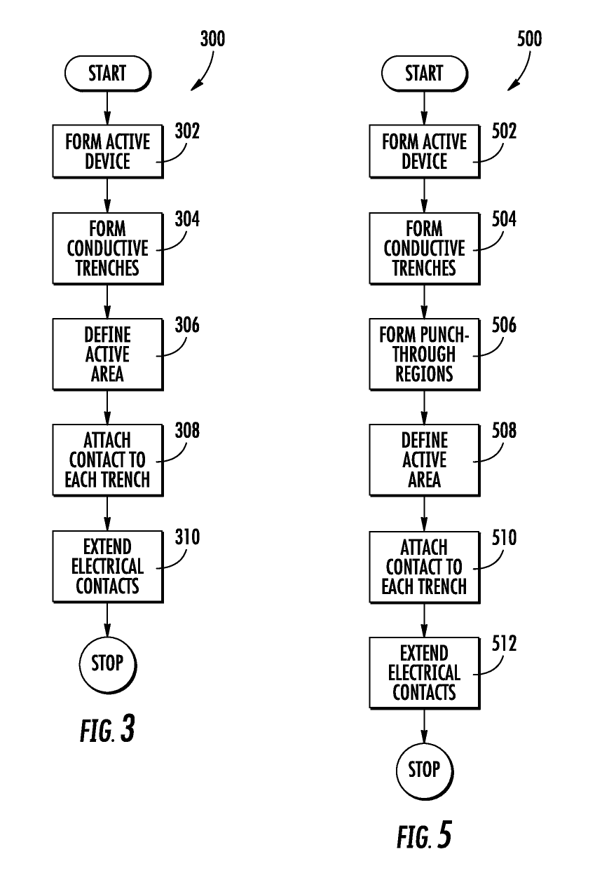

Notably, system 100 also includes a plurality of electrical contacts 101, 103. Each electrical contact 101, 103 is attached to a respective conductive trench formed in photo-detector unit 102 (e.g., described in detail below with respect to FIG. 2). An adjustable voltage generator (e.g., differential voltage generator) 106 can be connected to the cathode connections of photo-detector unit 102 via each electrical contact 101, 103. If the frequency of the differential voltage generated by adjustable (e.g., differential) voltage generator 106 is the same frequency as that of a modulated, incident light signal detected by photo-detector unit 102, photo-detector unit 102 demodulates the detected incident light signal and outputs a direct current (DC) signal that can be utilized to determine the phase of the detected incident light signal. More precisely, for example, multiplying two sinusoidal signals of the same frequency creates a DC component that is proportional to the product of their amplitudes. If the control signal is known, the amplitude of the other signal can thus be derived using a DC measurement. The DC signals that are output from the demodulator (e.g., photo-detector unit 102) represent the in-phase and quadrature-phase (IQ) component vectors of the detected incident light signal. The combination of these components can be used to completely reconstruct the detected incident light signal in accordance with accepted IQ demodulation principles. Specifically, the phase of the detected incident light signal can be derived from the DC components by calculating the inverse tangent of the ratio of the DC components.

The upper frequency for the modulated incident light signal that can be detected by photo-detector unit 102 is limited by the magnitude of the lateral electric field in an active area of photo-detector unit 102 (e.g., due to the saturation velocity of carriers in the silicon). Consequently, system 100 enables a designer to control the differential voltage signal applied to the plurality of conductive trenches in photo-detector unit 102 and, therefore, the designer can control and maximize the magnitude of the lateral electric field within photo-detector unit 102.

FIG. 2 is a side elevation, cross-sectional view of a semiconductor device 200, which can be utilized to implement one embodiment of the present invention. FIG. 3 is a flowchart showing an exemplary process 300, which can be utilized to fabricate the semiconductor device 200 shown in FIG. 2. Note that the process 300 illustrated herein can be utilized in connection with the fabrication of a P-channel semiconductor device (e.g., Metal-Oxide Semiconductor Field Effect Transistor or MOSFET). However, it should be understood that the process shown is equally applicable to the fabrication of N-channel semiconductor devices, or other semiconductor structures and the like. Also note that, for clarity, the process 300 shown herein includes certain illustrative steps and does not show a number of conventional semiconductor fabrication steps that might be utilized in such a process.

Referring to FIGS. 2 and 3, the first step (302) of the process is to form an active device (e.g., diode, transistor) within the semiconductor device 200. In one embodiment, an active device can be fabricated by forming a first region 204 of a first polarity type (e.g., N-type) over a suitable substrate material 202. For example, the first region 204 can be formed so that the surface of a semiconductor wafer is N-type, and the substrate material 202 can be formed utilizing a P-type substrate material. Utilizing a suitable implantation method, an impurity of a second polarity type (e.g., P-type) is implanted in the first region 204 and driven (e.g., by annealing) to form a region of the second polarity type 206 (e.g., P-channel region) over the first region 204.

Next, utilizing a suitable masking and etching method (step 304), a first conductive trench 208 and a second conductive trench 210 are formed by etching downwardly into the channel region 206. Utilizing a suitable deposition method, the first conductive trench 208 and second conductive trench 210 are then filled with a layer of, for example, a material of the first polarity type (e.g., n-type). For example, each conductive trench 208, 210 can be formed utilizing a suitable poly-silicon (e.g., n-type poly-silicon) material, or any other suitable material that can be utilized to form a conductive trench. For example, in one embodiment, and purely as a design constraint, each conductive trench 208, 210 thus formed can be approximately fifteen (15) micrometers deep and 0.5 micrometers wide.

In any event, an active area 212 is defined (step 306) between the two conductive trenches 208, 210. The active area 212 will define the extent of an electrical field 213 during operation of the semiconductor device. For example, in a photo-detector device, the active area 212 will define the extent of a lateral electric field 213 during operation of the photo-detector device. Note that the electric field 213 should extend throughout the entire volume of material between trenches 208, 210, and not just the surface. Next, utilizing a suitable metallization method (step 308), a first electrical contact 214 is attached to a surface of conductive trench 208, and a second electrical contact 216 is attached to a surface of conductive trench 210. The first and second electrical contacts 214, 216 can be extended (step 310) to form an external connection for a voltage generator to connect to the first and second electrical contacts 214, 216.

In operation, a voltage (e.g., differential voltage) is applied to each electrical contact 214, 216 to control the magnitude of the electrical field 213 (e.g., lateral electric field) generated within the active area 212. Notably, although a particular buried device configuration is shown in FIG. 2, a semiconductor device utilizing a different configuration for a buried device can be implemented and utilized with a plurality of conductive trenches and electrical contacts in a manner similar to that described above.

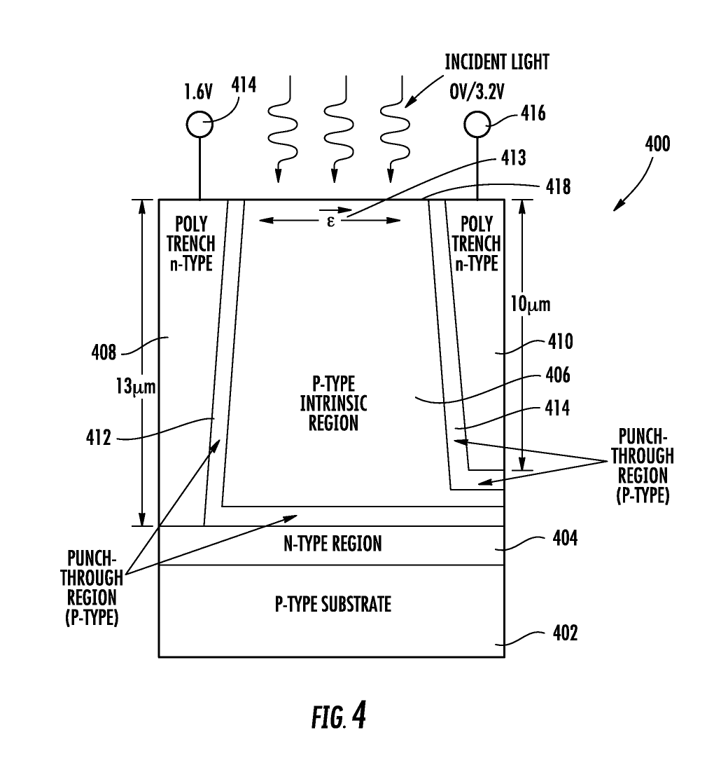

FIG. 4 is a side elevation, cross-sectional view of a semiconductor device 400, which can be utilized to implement a second embodiment of the present invention. FIG. 5 is a flowchart showing an exemplary process 500, which can be utilized to fabricate the semiconductor device shown in FIG. 4. Note that the process 500 illustrated herein can be utilized in connection with the fabrication of a P-channel semiconductor device (e.g., MOSFET). However, it should be understood that the process shown is equally applicable to the fabrication of N-channel semiconductor devices, or other semiconductor structures and the like. Also note that, for clarity, the process 500 shown herein includes certain illustrative steps and does not show the conventional semiconductor fabrication steps that might be utilized in such a process.

Referring to FIGS. 4 and 5, the first step (502) of the process is to form an active device (e.g., diode, transistor) within the semiconductor device 400. In one embodiment, an active device can be formed by forming a first region 404 of a first polarity type (e.g., N-type) over a suitable substrate material 402. For example, the first region 404 can be an N-type buried layer (NBL) formed from the surface of an N-type semiconductor wafer, and the substrate material 402 can be formed utilizing a P-type substrate material. Utilizing a suitable method, for example epitaxial growth, an impurity of a second polarity type (e.g., P-type) is introduced to form an intrinsic region (e.g., channel region) 406 of the second polarity type (e.g., P-type intrinsic region) over a portion of first region 404. In one embodiment, and purely as a design constraint, the intrinsic region 406 can be approximately one (1) micrometer wide.

Next, utilizing a suitable masking and etching method (step 504), a first conductive trench 408 and a second conductive trench 410 are formed by etching downwardly into the intrinsic region 406. Utilizing a suitable deposition method, the first conductive trench 408 and second conductive trench 410 are then filled with a layer of, for example, a material of the first polarity type (e.g., N-type). For example, each conductive trench 408, 410 can be formed with a suitable poly-silicon (e.g., N-type poly-silicon) material, or any other suitable material that can be utilized to form a conductive trench. For example, in one embodiment, first conductive trench 408 thus formed can be approximately thirteen (13) micrometers deep, and second conductive trench 410 can be approximately ten (10) micrometers deep. Note that by forming such conductive trenches with different depths, a user is enabled to apply a differential voltage or a fixed voltage to either conductive trench (e.g., as described in more detail below). In addition, the intrinsic region 406 is now completely enclosed by regions of the opposite doping polarity (e.g., N-type), which prevents leakage of photo-generated carriers to the substrate 402.

Next, in one embodiment, utilizing a suitable implantation method (step 506), an increased dose of an impurity of the second polarity type (e.g., P-type) is implanted in the intrinsic region 406 at its boundary with the first conductive trench 408 and the first region 404 to form a first punch-through region 412. For example, depending on the operational application involved, a P-type dopant (e.g., Boron) with a dose within the range 1e12-1e13 cm⁻² and an energy level of less than 25 keV can be used to form the first punch-through region 412. A similar increased dose of the impurity of the second polarity type (e.g., P-type) is also implanted in the intrinsic region 406 at its boundary with the second conductive trench 410 to form a second punch-through region 414. Consequently, by selecting suitable dopant concentrations in forming the punch-through regions 412, 414, the trench-to-trench leakage currents in semiconductor device 400 can be significantly reduced, and the overall sensitivity of the semiconductor device can be increased. Also, by controlling the dopant concentrations in the punch-through regions 412, 414, a designer has increased flexibility with respect to selecting speed/sensitivity performance tradeoffs for the semiconductor device involved.

In any event, an active area 418 is defined (step 508) by its location within the intrinsic region 406 and between the two conductive trenches 408, 410. The active area 418 will define the extent of an electrical field 413 during operation of the semiconductor device. For example, in a photo-detector device, the active area 418 will define the extent of a lateral electric field 413 during operation of the photo-detector device. Next, utilizing a suitable metallization method (step 510), a first electrical contact 414 is attached to a surface of conductive trench 408, and a second electrical contact 416 is attached to a surface of conductive trench 410. The first and second electrical contacts 414, 416 can be extended (step 512) to form an external connection for a voltage generator to connect to the first and second electrical contacts 414, 416.

In operation, a voltage signal (differential or fixed voltage signal) is applied to each electrical contact 414, 416 to control the magnitude of the electrical field 413 (e.g., lateral electric field) generated within the active area 418. Notably, although a particular buried device configuration is shown in FIG. 4, a semiconductor device utilizing a different configuration for a buried device can be implemented and utilized with a plurality of conductive trenches and electrical contacts in a manner similar to that described above.

In the discussion and claims herein, the term “on” used with respect to two materials, one “on” the other, means at least some contact between the materials, while “over” means the materials are in proximity, but possibly with one or more additional intervening materials such that contact is possible but not required. Neither “on” nor “over” implies any directionality as used herein. The term “conformal” describes a coating material in which angles of the underlying material are preserved by the conformal material. The term “about” indicates that the value listed may be somewhat altered, as long as the alteration does not result in nonconformance of the process or structure to the illustrated embodiment.

Terms of relative position as used in this application are defined based on a plane parallel to the conventional plane or working surface of a wafer or substrate, regardless of the orientation of the wafer or substrate. The term “horizontal” or “lateral” as used in this application is defined as a plane parallel to the conventional plane or working surface of a wafer or substrate, regardless of the orientation of the wafer or substrate. The term “vertical” refers to a direction perpendicular to the horizontal. Terms such as “on,” “side” (as in “sidewall”), “higher,” “lower,” “over,” “top,” and “under” are defined with respect to the conventional plane or working surface being on the top surface of the wafer or substrate, regardless of the orientation of the wafer or substrate.

Although specific embodiments have been illustrated and described herein, it will be appreciated by those of ordinary skill in the art that any arrangement, which is calculated to achieve the same purpose, may be substituted for the specific embodiments shown. Therefore, it is manifestly intended that the present invention be limited only by the claims and the equivalents thereof.

What is claimed is:

1. An imaging system, comprising:
a photo-detector unit including a plurality of conductive trenches formed within the photo-detector unit, and a plurality of electrical contacts, each electrical contact connected to a respective conductive trench;
a light data processor unit coupled to an output of the photo-detector unit to convert an analog signal received from the photo-detector unit to a digital signal;
a processing unit coupled to an output of the light data processor unit to generate a control signal in response to the digital signal; and
a display unit coupled to an output of the processing unit to vary the intensity of an image displayed in response to the control signal.

2. The system of claim 1, further comprising:
an intrinsic region formed within the photo-detector unit; and
a punch-through region formed between the intrinsic region and at least one of the conductive trenches.

3. The system of claim 1, further comprising a voltage generator connected to the plurality of electrical contacts to generate a voltage signal and control a magnitude of a lateral electric field within the photo-detector unit.

4. The system of claim 1, wherein the light data processor unit includes at least one of an analog signal processor (ASP) and an analog-to-digital converter (ADC).

5. The system of claim 1, wherein the display unit comprises at least one of an optical light-emitting diode (OLED) display and a liquid crystal display (LCD).

6. The system of claim 1, wherein the system comprises at least one of a complementary metal-oxide semiconductor (CMOS) image sensor system, a light sensor system, a proximity sensor system, an infrared (IR) sensor system, and a CMOS time-of-flight optical sensor system.

7. The system of claim 1, wherein the system comprises at least one of a digital camera, an IR camera, a handheld or portable display, a Personal Digital Assistant (PDA), and a smart phone.

8. A semiconductor device, comprising:
a first conductive trench including a first semiconductor material of a first polarity type;
a second conductive trench including a second semiconductor material of the first polarity type, wherein the first and second conductive trenches are formed in a third semiconductor material of a second polarity type, and the first conductive trench and the second conductive trench define an active area therebetween;
a first electrical contact connected to a surface of the first conductive trench; and
a second electrical contact connected to a surface of the second conductive trench.

9. The semiconductor device of claim 8, further comprising:
a region of the second polarity type formed in the third semiconductor material and adjacent to a sidewall of at least one of the first conductive trench and the second conductive trench.

10. The semiconductor device of claim 9, wherein the region comprises a punch-through region.

11. The semiconductor device of claim 8, wherein the first conductive trench and the second conductive trench each comprise a polysilicon trench.

12. The semiconductor device of claim 8, wherein the semiconductor device is a silicon-based semiconductor device.

13. The semiconductor device of claim 8, wherein the semiconductor device is a photo-detector device.

14. The semiconductor device of claim 8, wherein the first polarity type is an N-type, and the second polarity type is a P-type.

15. The semiconductor device of claim 8, wherein the first polarity type is a P-type, and the second polarity type is an N-type.

16. The semiconductor device of claim 8, wherein the active area is operable to generate an electric field.

17. The semiconductor device of claim 8, wherein the semiconductor device is a photo-detector device and the active area is operable to generate a lateral electric field.

18. The semiconductor device of claim 8, wherein a depth of at least one of the first conductive trench and the second conductive trench is within a range between 0.7 micrometers and 13.0 micrometers.

19. A method of manufacture of a photo-detector device, comprising:
forming an active device within the photo-detector device;
forming a first conductive trench in the active device;
attaching a first electrical contact to a surface of the first conductive trench;
forming a second conductive trench in the active device;
attaching a second electrical contact to a surface of the second conductive trench;
forming an active area between the first conductive trench and the second conductive trench; and
forming a connection for a voltage generator to connect to the first electrical contact and the second electrical contact.

20. The method of claim 19, further comprising
forming an intrinsic region of a first polarity type in the active device; and
forming a region of the first polarity type in the intrinsic region and adjacent to a sidewall of at least one of the first conductive trench and the second conductive trench.

21. The method of claim 20, wherein the forming the region of the first polarity type in the intrinsic region comprises forming a punch-through region.

22. The method of claim 19, wherein the forming the connection further comprises forming the connection for a differential voltage generator to generate a differential voltage signal and control a magnitude of a lateral electric field with the differential voltage signal.

23. The method of claim 19, wherein the forming a first conductive trench comprises forming the first conductive trench with a semiconductor material of a first polarity type, and the forming the second conductive trench comprises forming the second conductive trench with a semiconductor material of the first polarity type.

24. The method of claim 19, wherein the forming the first and second conductive trenches further comprise forming the first and second conductive trenches in a third semiconductor material of a second polarity type.

25. The method of claim 19, wherein the forming integrates the photo-detector device monolithically with at least one other semiconductor device.

26. A method of controlling an electric field in a semiconductor device, comprising:
generating a voltage signal;
coupling the voltage signal to a first conductive trench and a second conductive trench in the semiconductor device;
adjusting the voltage signal; and
controlling a magnitude of the electric field in the semiconductor device.

27. The method of claim 26, wherein the generating comprises generating a differential voltage signal.

28. The method of claim 26, wherein the coupling comprises coupling the voltage signal to the first conductive trench and the second conductive trench of a photo-detector device.

29. The method of claim 26, wherein the controlling comprises controlling the magnitude of a lateral electric field in an active area of the semiconductor device.

30. The method of claim 26, further comprising increasing a frequency of a light signal to be detected by the semiconductor device.
